(19) United States
(12) Patent Application Publication
(10) Pub. No.: US 2014/0055952 A1
(43) Pub. Date: Feb. 27, 2014

(54) ELECTRONIC DEVICE WITH FAN MODULE

(71) Applicant: ZHENG-HENG SUN, Tu-Cheng (TW)

(72) Inventor: ZHENG-HENG SUN, Tu-Cheng (TW)

(21) Appl. No.: 13/627,988

(22) Filed: Sep. 26, 2012

(30) Foreign Application Priority Data
Aug. 24, 2012 (CN) 2012103046629

(51) Int. Cl. H05K 7/20

(52) U.S. Cl. 361/695

(57) ABSTRACT

An electronic device includes a sidewall and a fan module. The fan module includes a first support bracket mounted on an inner surface of the sidewall, a second support bracket mounted on the inner surface of the sidewall and spaced from the first support bracket, and a number of fans sandwiched between the first support bracket and the second support bracket. The sidewall, the first support bracket, the second support bracket, and the fans cooperatively bound a receiving slot for receiving cables of the electronic device. The first and second support bracket each defines a cutout adjacent to the sidewall and communicating with the receiving slot for allowing some of the cables to extend out of the receiving slot.

### BACKGROUND

1. Technical Field

The present disclosure relates to electronic devices, and particularly, to an electronic device with a fan module.

2. Description of Related Art

A plurality of fans can be installed in the computers or servers to dissipate heat. The fans are electrically connected to power modules through cables. However, in a disorderly fashion, the cables will occupy a large space in the computers or servers, thus reducing heat dissipating efficiency of the computers or severs.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electronic device, wherein the electronic device includes a fan module.

FIG. 2 is an enlarged view of the fan module of FIG. 1, but viewed from another perspective.

FIG. 3 is an assembled, isometric view of the electronic device of FIG. 1.

FIG. 4 is a cross-sectional view of FIG. 3, taken along the line of IV-IV.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

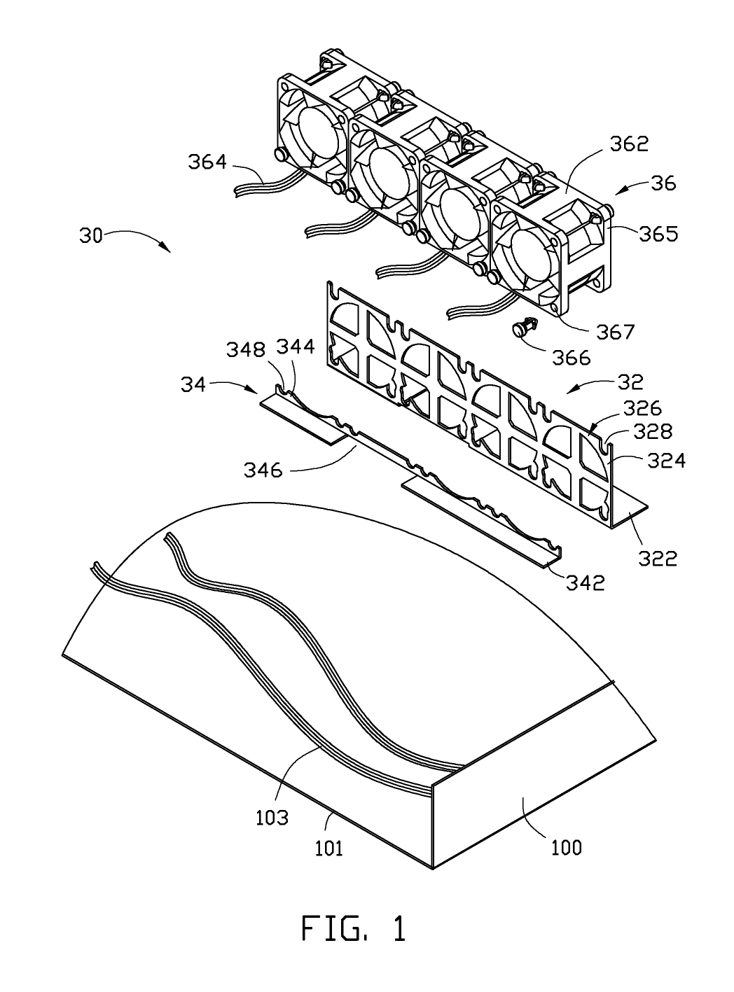

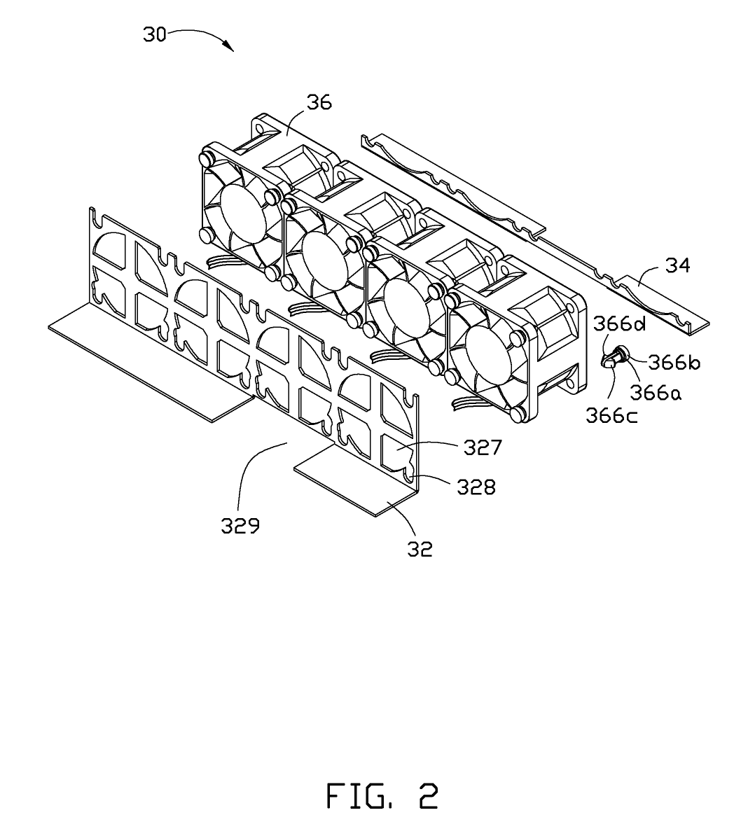

Referring to FIG. 1 and FIG. 2, an exemplary embodiment of an electronic device includes an enclosure 100 and a fan module 30. The enclosure 100 includes a sidewall 101 and a plurality of cables 103 received in the enclosure 100.

The fan module 30 includes a first support bracket 32, a second support bracket 34, and a plurality of fans 36.

The first support bracket 32 includes a first mounting plate 322 and a support plate 324 perpendicularly extending up from a side of the first mounting plate 322. A plurality of vent areas 326 is longitudinally formed on the support plate 324. Each vent area 326 defines a plurality of vents 327. The support plate 324 defines four slots 328, respectively at four corners of each vent area 326. The slots 328 at top corners of each of the vent areas 328 extend through the top edge of the support plate 324. The slots 328 at bottom corners of each of the vent areas 326 communicate with two corresponding vents 327 of the vent area 326. The first mounting plate 322 defines a cutout 329 extending through a bottom of the support plate 324.

The second support bracket 34 includes a second mounting plate 342 and a flange 344 perpendicularly protruding up from a side of the second mounting plate 342. The second mounting plate 342 defines a cutout 346 extending through a bottom of the flange 344. The flange 344 defines a plurality of slots 348 extending through a top edge of the flange 344.

Each fan 36 includes a rectangular main body 362, a plurality of cables 364 connected to the main body 326, and six fastening members 366. The main body 362 includes two opposite side plates 365. Four corners of each side plate 365 respectively define four fixing holes 367. Each fastening member 366 includes a cylindrical abutting portion 366a, a cylindrical stopping portion 366b extending out from a first end of the abutting portion 366a, and a latching portion 366c extending out from a second end of the abutting portion 366a opposite to the stopping portion 366b. The latching portion 366c includes two opposite resilient hooks 366d extending out from the abutting portion 366a. A diameter of the abutting portion 366a is less than a diameter of the stopping portion 366b, the diameter of the abutting portion 366a is greater than a diameter of the corresponding fixing hole 367, and a thickness of the abutting portion 366a is equal to the thicknesses of each of the support plate 324 and the flange 344.

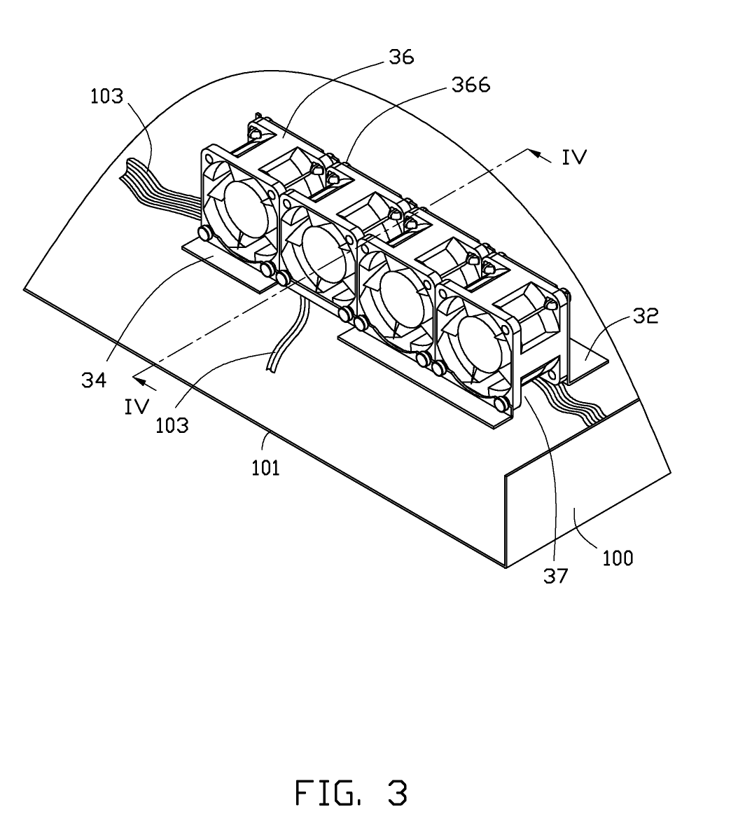

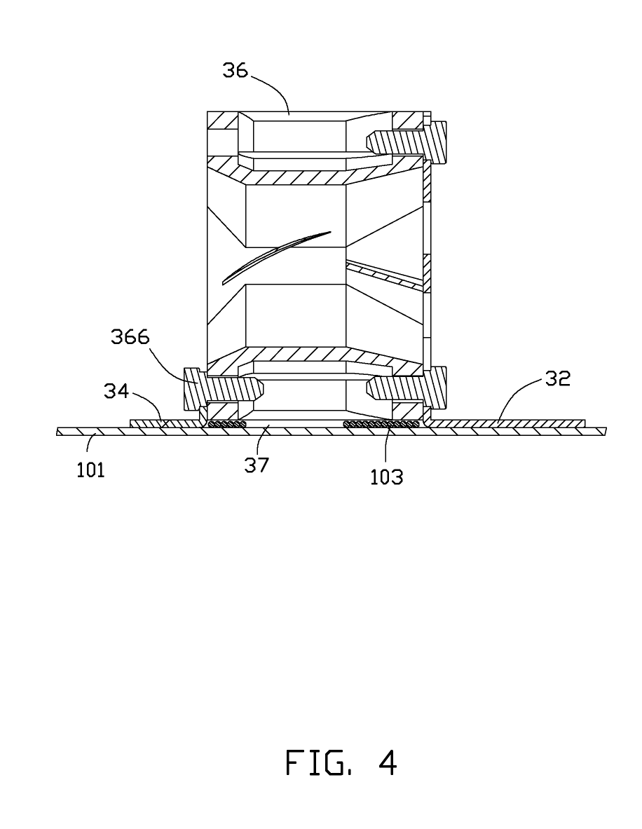

Referring to FIG. 3 and FIG. 4, in assembly, the first mounting plate 322 of the first support bracket 32 is mounted on an inner surface of the sidewall 103 by screwing or clamping, and the second mounting plate 342 of the second support bracket 34 is mounted on the inner surface of the sidewall 103 by screwing or clamping and is spaced from the first support bracket 32. The support plate 324 faces the flange 344. A distance between the support plate 324 and the flange 344 is equal to a thickness of the fans 36.

The six fastening members 366 are fastened to the fixing holes 367 of each fan 36, with four fastening members 366 located at four corners of one side plate 365 and two fastening members 366 located at two lower corners of the other side plate 365. The hooks 366d of each fastening member 366 are deformed toward each other. The deformed hooks 366d are inserted into a corresponding fixing hole 367 from an outer side of the corresponding side plate 365, until distal ends of the hooks 366d pass through the fixing hole 367. The hooks 366d are restored and snappingly engage with an inner surface of the side plate 365.

In use, the cables 103 is received between the support plate 324 and the flange 344. The fans 36 are placed between the support plate 324 and the flange 344. The abutting portion 366a of each fastening member 366 is inserted into the corresponding slots 328 and 348. The stopping portions 366b respectively abut outer surfaces of the support plate 324 and the flange 344. The fans 36 are thus attached between the support plate 324 and the flange 344, and are aligned with the corresponding vent areas 326. The support plate 324, the flange 344, the sidewall 101, and the fans 36 cooperatively bound a receiving slot 37 for receiving the cables 103 and the cables 364 of the fans 36. A part of the cables 103 can be extended out of the receiving slot 37 through the cutouts 329 and 346. In the embodiment, a distance between the sidewall 101 and the fans 36 is greater than 1 millimeter.

In disassembly, the combination of each fan 36 and the corresponding fastening members 366 is detached from the support plate 324 and the flange 344 by disengaging the abutting portions 366a from the corresponding slots 328 and 348.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. An electronic device, comprising:
a sidewall; and
a fan module comprising a first support bracket mounted on an inner surface of the sidewall, a second support bracket mounted on the inner surface of the sidewall and spaced from the first support bracket, and a plurality of fans sandwiched between the first support bracket and the second support bracket;
wherein the sidewall, the first support bracket, the second support bracket, and the fans cooperatively bound a receiving slot, one of the first and second support bracket defines a cutout adjacent to the sidewall and communicating with the receiving slot.

2. The electronic device of claim 1, further comprising a plurality of cables received in the receiving slot, wherein a part of the cables extends out of the receiving slot through the cutout.

3. The electronic device of claim 2, wherein the first support bracket comprises a first mounting plate mounted on the sidewall and a support plate extending up from a side of the first mounting plate, the second support bracket comprises a second mounting plate mounted on the sidewall and a flange protruding up from a side of the second mounting plate, the fans are sandwiched between the support plate and the flange, the support plate, the fans, the flange, and the sidewall cooperatively bound the receiving slot.

4. The electronic device of claim 3, wherein the cutout is defined in the first mounting plate and extends through a bottom of the support plate.

5. The electronic device of claim 3, wherein the cutout is defined in the second mounting plate extending through a bottom of the flange.

6. The electronic device of claim 3, wherein a plurality of vent areas is longitudinally formed on the support plate, the support plate defines four first slots at four corners of each vent area, the flange defines a plurality of second slots, each fan comprises two opposite side plates, four corners of each side plate define four fixing holes, a plurality of fastening members respectively extends through the first and second slots and is latched in the fixing holes.

7. The electronic device of claim 6, wherein each fastening member comprises an abutting portion latched in the first slot or the second slot, a stopping portion extending out from a first end of the abutting portion and abutting an outer surface of the support plate or the flange, and a latching portion extending out from a second end of the abutting portion opposite to the stopping portion and latched in a corresponding fixing hole of the corresponding side plate of the fan.
